(19) United States
(12) Patent Application Publication
(10) Pub. No.: US 2009/0185410 A1
(43) Pub. Date: Jul. 23, 2009

(54) METHOD AND SYSTEM FOR PROVIDING SPIN TRANSFER TUNNELING MAGNETIC MEMORIES UTILIZING UNIDIRECTIONAL POLARITY SELECTION DEVICES

(75) Inventors: Yiming Huai, Pleasanton, CA (US); Eugene Chen, Fremont, CA (US); Frank Albert, San Diego, CA (US); Jia-Hwang Chang, Saratoga, CA (US)

Correspondence Address: STRATEGIC PATENT GROUP, P.C., P.O. BOX 1329, MOUNTAIN VIEW, CA, 94042, US

(73) Assignee: GRANDIS, INC., Milpitas, CA (US)

(21) Appl. No.: 12/017,532

(22) Filed: Jan. 22, 2008

(51) Int. Cl. G11C 11/02

(52) U.S. Cl. 365/158

(57) ABSTRACT

A magnetic memory cell and a magnetic memory incorporating the cell are described. The magnetic memory cell includes at least one magnetic element and a plurality of unidirectional polarity selection devices. The magnetic element(s) are programmable using write current(s) driven through the magnetic element. The unidirectional polarity selection devices are connected in parallel and such that they have opposing polarities. The magnetic memory may include a plurality of magnetic storage cells, a plurality of bit lines corresponding to the plurality of magnetic storage cells, and a plurality of source lines corresponding to the plurality of magnetic storage cells.

### BACKGROUND OF THE INVENTION

FIGS. 1-3 depict a small portion of a conventional spin transfer torque random access memory (STT-RAM) 1. FIG. 1 depicts a circuit diagram of the portion of the conventional STT-RAM 1, while FIG. 2 depicts a cross-sectional view of the portion of the conventional STT-RAM 1. FIG. 3 depicts a greater portion of the conventional STT-RAM 1. The conventional STT-RAM 1 includes a conventional magnetic storage cell 10 including a conventional magnetic element 12 and a conventional selection device 14 that is preferably an isolation transistor 14, word line 24, source line 26, and bit line 28. The source line 26 is shown oriented perpendicular to the bit line 28. However, the source line 26 is typically either parallel or perpendicular to the bit line 28, depending on specific architecture used for the conventional STT-RAM 1. In addition, the column selector/drivers 52 and 56 as well as the word line selector/driver 54 are shown,

The conventional magnetic element 12 may be a magnetic tunneling junction (MTJ) or other analogous magnetic element and is configured to be changeable between resistance states by driving a current through the conventional magnetic element 12. The current changes state of the conventional magnetic element 12 using the spin transfer torque switching effect. Typically, this is achieved by ensuring that the conventional magnetic element 12 has a sufficiently small cross-sectional area and that the layers of the magnetic element, such as pinned, spacer and free layer (not separately shown) have particular thicknesses. When the current density is sufficient, the current carriers driven through the conventional magnetic element 12 may impart sufficient torque to change the state of the conventional magnetic element 12. When a write current is driven in one direction, the state may be changed from a low resistance state to a high resistance state. When the write current is driven in the opposite direction, the state may be changed from a high resistance state to a low resistance state.

The conventional selection device 14 is typically a conventional transistor, such as a MOSFET. The conventional transistor 14 includes a conventional source 16, a conventional gate 18, a conventional drain 20, and a conventional gate oxide 22. The conventional source 16 and conventional drain 20 are typically N-doped and reside in a P-well 15 formed within the substrate 13. The conventional transistor 14 is a multi-directional device because the conventional transistor 14 can support current flowing in multiple directions. In particular, current may flow from the bit line 28 through conventional magnetic element 12, through the transistor 14 and to the source line 26. Alternatively, current may flow from the source line 26, through the transistor 14, through the conventional magnetic element 12 to the bit line 28. The conventional transistor 14 includes a source 16, a conventional gate 18, and a conventional drain 20. When a threshold voltage is applied to the conventional gate 18 through the conventional word line 24 current can flow between the conventional source 16 and the conventional drain 20 as described above. This current may be used in programming the conventional magnetic element 12 via spin transfer.

In order to program the conventional storage cell 10, the conventional word line 24 and thus the conventional transistor 14 are activated using the word line selector/driver 54. Thus, a voltage is applied to the gate of the conventional transistor 14. In the conventional STT-RAM 1, therefore, the conventional transistor 14 may be viewed as acting in an analogous manner to a switch. A current is driven between the conventional source line 26 and the conventional bit line 28 by supplying a high voltage to the conventional bit line 28 and a low voltage, such as ground, to the conventional source line 26, or vice versa using drivers 52 and 56. For a read operation, the bit line 28 and the word line 24 are activated using reading/writing column selector/driver 52 and word line selector/driver 54, respectively. Consequently, the conventional transistor 14 is turned on. A read current is driven through the conventional magnetic element 12. In order to ensure that the conventional storage cell 10 is not written during a read operation, the read current is typically less than the write current. Thus, the conventional magnetic storage cell 10 can be programmed and read.

Although the conventional STT-RAM 1 functions, one of ordinary skill in the art will recognize that there are drawbacks. In particular, there may be barriers to allowing the conventional STT-RAM 1 to be integrated at higher densities. The required switching current for a thermally stable conventional magnetic element 10 is relatively large. In addition, the magnitude of the current through the conventional magnetic element 12 may be limited by the amount of current that can pass through the conventional transistor 14. The current passing capability of the conventional transistor 14 is proportional to the width of the gate 18, which is measured perpendicular to the cross-section shown in FIG. 2. As the switching current increases, the conventional transistor 14 has a larger gate width to support the current. Although it may be possible to provide smaller conventional magnetic elements 12, larger conventional transistors 14 are used. The large size of the conventional transistors 14 increases the size of the conventional cells 10. Consequently, it is difficult to fabricate higher density cells 10.

Accordingly, what is desired is a method and system for providing and utilizing memory cells employing spin transfer based switching that may be extended to higher densities. The present invention addresses such a need.

### BRIEF SUMMARY OF THE INVENTION

A magnetic memory cell and a magnetic memory incorporating the cell are described. The magnetic memory cell includes at least one magnetic element and a plurality of unidirectional polarity selection devices. The magnetic element(s) are programmable using write current(s) driven through the magnetic element. The unidirectional polarity selection devices are connected in parallel and such that they have opposing polarities. The magnetic memory may include a plurality of magnetic storage cells, a plurality of bit lines corresponding to the plurality of magnetic storage cells, and a plurality of source lines corresponding to the plurality of magnetic storage cells

According to the method and system disclosed herein, the magnetic memory may be integrated to higher densities.

### BRIEF DESCRIPTION OF SEVERAL VIEWS OF THE DRAWINGS

FIG. 1 is a circuit diagram of a portion of a conventional magnetic random access memory employing the spin transfer effect.

FIG. 2 is a cross-sectional diagram of a portion of a conventional magnetic random access memory employing the spin transfer effect.

FIG. 3 is a diagram of a portion of a conventional magnetic memory employing the spin transfer effect.

FIG. 4 is a circuit diagram depicting an exemplary embodiment of a portion of a magnetic random access memory employing the spin transfer effect.

FIG. 5 is a cross-sectional diagram depicting an exemplary embodiment of a portion of a conventional magnetic memory employing the spin transfer effect.

FIG. 6 is a cross-sectional diagram depicting another exemplary embodiment of a portion of a conventional magnetic memory employing the spin transfer effect.

FIG. 7 is a diagram depicting an exemplary embodiment of a portion of a magnetic memory employing the spin transfer effect.

FIG. 8 is a diagram depicting another exemplary embodiment of a portion of a magnetic memory employing the spin transfer effect.

FIG. 9 is a diagram depicting another exemplary embodiment of a portion of a magnetic memory employing the spin transfer effect.

FIG. 10 is a diagram depicting an exemplary embodiment of a method for providing a portion of a magnetic memory employing the spin transfer effect.

FIG. 11 is a diagram depicting an exemplary embodiment of a method for providing a magnetic memory employing the spin transfer effect.

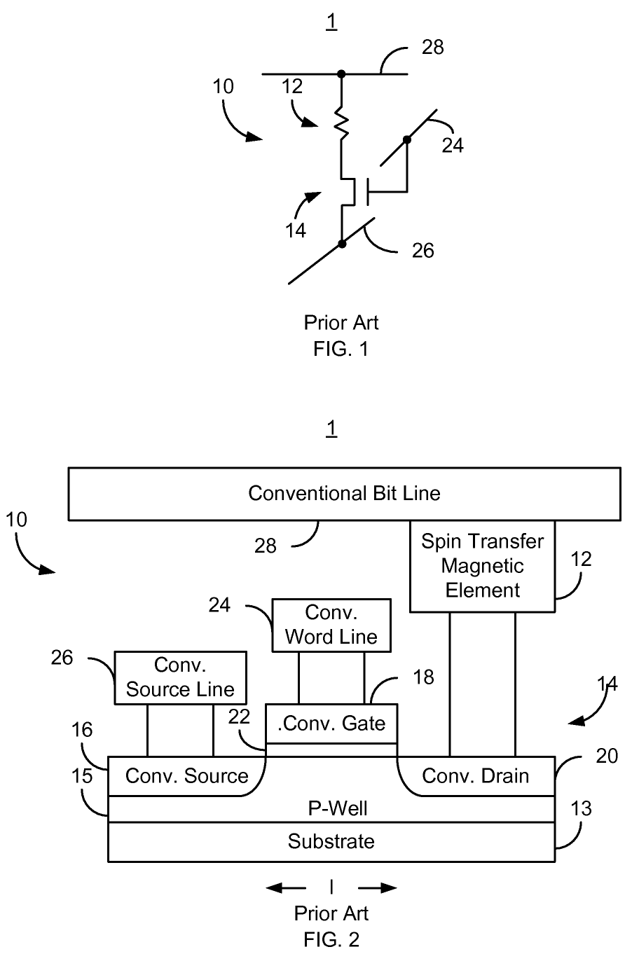

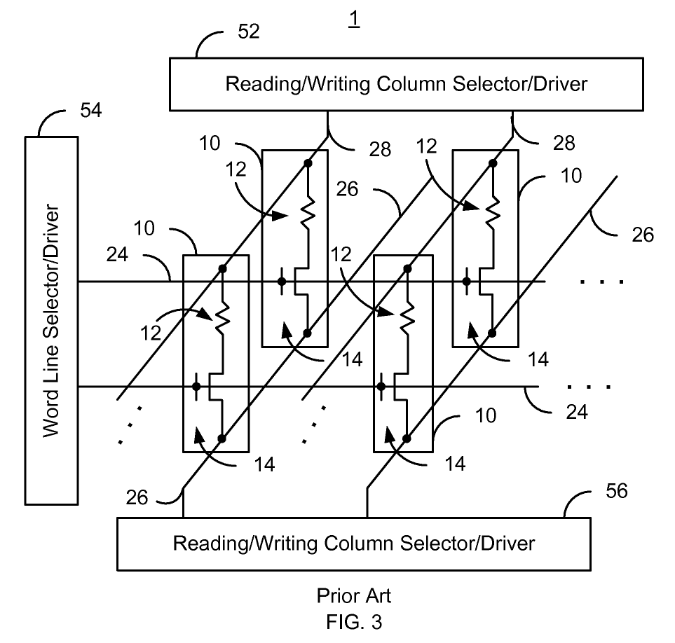

### DETAILED DESCRIPTION OF THE INVENTION

The present invention relates to magnetic memories. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

A magnetic memory cell and a magnetic memory incorporating the cell are described. The magnetic memory cell includes at least one magnetic element and at a plurality of unidirectional polarity selection devices. The magnetic element(s) are programmable using write current(s) driven through the magnetic element. The unidirectional polarity selection devices are connected in parallel and such that they have opposing polarities. The magnetic memory may include a plurality of magnetic storage cells, a plurality of bit lines corresponding to the plurality of magnetic storage cells, and a plurality of source lines corresponding to the plurality of magnetic storage cells.

The present invention is mainly described in terms of particular systems provided in particular implementations. However, one of ordinary skill in the art will readily recognize that this method and system will operate effectively in other implementations. For example, the diodes, magnetic storage cells, magnetic elements, and memories may take a number of different forms. For example, the magnetic memory is also described in the context of a magnetic random access memory (MRAM), but may take other forms. The present invention is also described in the context of writing using spin transfer. One of ordinary skill in the art will recognize that in some embodiments, spin transfer may be used in addition to or in lieu of other writing mechanisms. The present invention will also be described in the context of particular methods having certain steps. However, the method and system operate effectively for other methods having different and/or additional steps not inconsistent with the present invention. One of ordinary skill in the art will also recognize that for clarity, the drawings are not to scale.

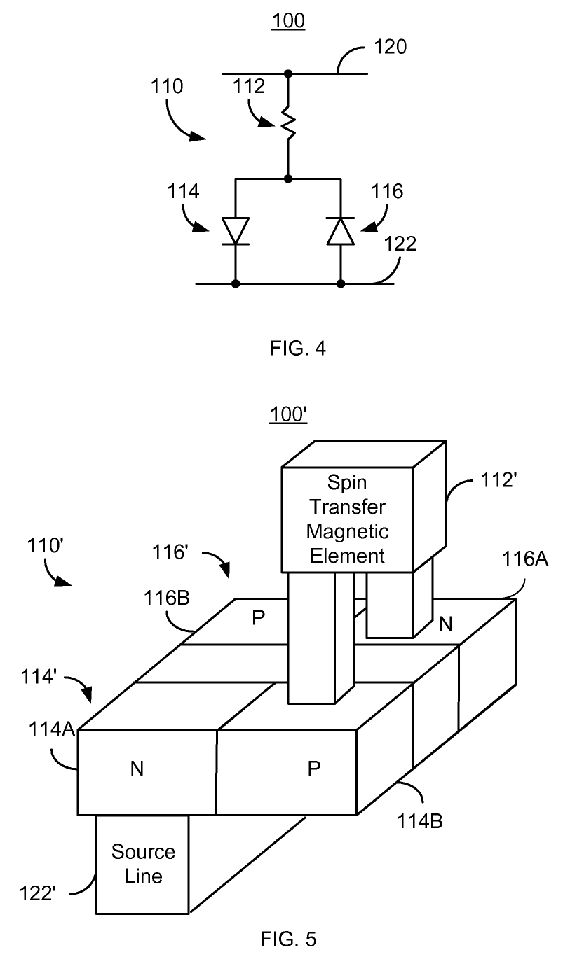

FIG. 4 is a circuit diagram depicting an exemplary embodiment of a portion of a magnetic memory 100 employing the spin transfer effect. In particular, an exemplary embodiment of a magnetic memory cell 110 is shown. Also depicted in FIG. 4 are bit line 120 and source line 122. Although only one magnetic memory cell 110, bit line 120, and source line 122 are shown, a memory typically includes a plurality of magnetic memory cells 110 arranged in an array as well as a number of bit lines 120 and source lines 122. Although shown as parallel, the bit line 120 and source line 122 may make another angle with each other. However, the source line 122 is typically either parallel perpendicular to the bit line 120, depending on specific architecture used for the magnetic memory 100. The magnetic storage cell 110 includes a magnetic element 112 and unidirectional polarity selection devices 114 and 116. Although one magnetic element 112 is shown, multiple magnetic elements might be used in the magnetic storage cell 110. The magnetic element 112 is coupled to the bit line 120, while the unidirectional polarity selection devices 114 and 116 are coupled in parallel to the source line 122.

The magnetic element 112 may be a spin valve, MTJ, dual spin valve, dual MTJ, or other analogous magnetic element and is configured to be changeable between resistance states by driving a current through the magnetic element 112. The current changes state of the magnetic element 112 using the spin transfer torque switching effect. Typically, this is achieved by ensuring that the magnetic element 112 has a sufficiently small cross-sectional area and that the layers of the magnetic element, such as pinned, spacer and free layer (not separately shown) have particular thicknesses. When the current density is sufficient, the current carriers driven through the magnetic element 112 may impart sufficient torque to change the state of the magnetic element 112. When a write current is driven in one direction, the state may be changed from a low resistance state to a high resistance state. When the write current is driven in the opposite direction, the state may be changed from a high resistance state to a low resistance state. Consequently, the magnetic element 112 may be written by current driven through the magnetic element 112.

The unidirectional polarity selection devices 114 and 116 are coupled in parallel. In addition, the unidirectional polarity selection devices 114 and 116 are configured such that their polarities are opposite. Thus, the unidirectional polarity selection device 114 conducts current in a first direction (top to bottom in FIG. 4) while the unidirectional polarity selection device 116 conducts current in a second direction opposite to the first direction (bottom to top in FIG. 4). Although two unidirectional polarity selection devices 114 and 116 are shown, another number may be used. However, the unidirectional polarity selection devices may still be coupled such that a portion of the unidirectional polarity selection devices conduct in one direction, while a remaining portion of the unidirectional polarity selection devices conduct in the other direction. In the embodiment shown, the unidirectional polarity selection devices 114 and 116 are diodes 114 and 116. In such an embodiment, the diode 114 carries current in the first direction (top to bottom in FIG. 4) while the diode 116 conducts current in the second direction (bottom to top in FIG. 4).

In operation, the magnetic element 112 is written to a first state by a write current driven from the bit line 120 to the source line 122. The diode 114 carries the write current when the magnetic element 112 is written to the first state. Because it has opposite polarity, the diode 116 is off. Thus, the write current does not flow through the diode 116 when writing to the first state. The magnetic element 112 is written to a second state by a write current driven from the source line 122 to the bit line 120. During such a write operation, the diode 116 carries the write current. Because it has opposite polarity, the diode 114 is off. Thus, the write current does not flow through the diode 114 when writing to the second state. However, current flows through one of the diodes 114 or 116 when the magnetic element 112 is being written. When reading, a read current is driven through the magnetic element 112. In one embodiment, the read current may be driven from the bit line 120 to the source line 122 through the diode 114. In another embodiment, the read current may be driven from the source line 122 to the bit line 120. In one embodiment, the read current is sufficiently smaller than the write current that the magnetic element 112 is not inadvertently written. Thus, the magnetic memory 100 can be written to and read.

FIG. 5 is a cross-sectional diagram depicting an exemplary embodiment of a portion of a conventional magnetic memory 100′ employing the spin transfer effect. The magnetic memory 100′ is analogous to the magnetic memory 100. Consequently, analogous portions of the magnetic memory 100′ are labeled similarly. Thus, the magnetic memory 100′ includes a magnetic memory cell 110′ including magnetic element 112′ and unidirectional polarity selection devices 114′ and 116′. Also shown is source line 122′. For clarity, the bit line is not shown.

Although only one magnetic memory cell 110′ and source line 122′ are shown, a memory typically includes a plurality of magnetic memory cells 110′ arranged in an array as well as a number of bit lines (not shown) and source lines 122′. In addition, although one magnetic element 112′ is shown, multiple magnetic elements might be used in each cell 110′. The magnetic element 112′ is coupled to the bit line (not shown), while the unidirectional polarity selection devices 114′ and 116′ are coupled to the source line 122′. The magnetic element 112′ may be a spin valve, MTJ, dual spin valve, dual MTJ, or other analogous magnetic element and is configured to be changeable between resistance states by driving a current through the magnetic element 112′. The current changes state of the magnetic element 112′ using the spin transfer torque switching effect.

The unidirectional polarity selection devices 114′ and 116′ are coupled in parallel. In addition, the unidirectional polarity selection devices 114′ and 116′ are configured such that their polarities are opposite. The unidirectional selection devices 114′ and 116′ are planar diodes. Thus, the diode 114′ conducts current in a first direction (from the magnetic element 112′ to the source line 122′) while the diode 116′ conducts current in a second direction opposite to the first direction (from the source line 122′ to the magnetic element 112′). Although two diodes 114′ and 116′ are shown, another number may be used. In operation, the magnetic memory 100′ functions in an analogous manner to the magnetic element 100. In the embodiment shown, the diodes 114′ and 116′ are planar diodes. Thus, the diode 114′ includes N-region 114A and P-region 114B. Similarly, the diode 116′ includes N-region 116A and P-region 116B.

The magnetic memory 100′ functions in an analogous manner to the magnetic memory 100. Thus, the write current used to set the magnetic element 112′ to a first state is driven in a first direction passes through the magnetic element 112′ and the diode 114′ to the source line 122′. The write current used to set the magnetic element 112′ to a second state is driven in a second direction passes from the source line 122′ and the diode 116′ to the magnetic element 112′. When reading, a read current is driven through the magnetic element 112′. In one embodiment, the read current may be driven in from magnetic element 112′ to the source line 122′ through the diode 114′. In another embodiment, the read current may be driven from the source line 122′, through the diode 116′ and through the magnetic element 112′. In one embodiment, the read current is sufficiently smaller than the write current that the magnetic element 112′ is not inadvertently written. Thus, the magnetic memory 100′ can be written to and read. In addition, the local source line 122′ is underneath the diodes 114′ and 116′ in the embodiment shown. As a result, the magnetic storage cells 110′ may have a higher density. In addition to being written and read, the magnetic memory 100′ may be able to be fabricated at a higher density.

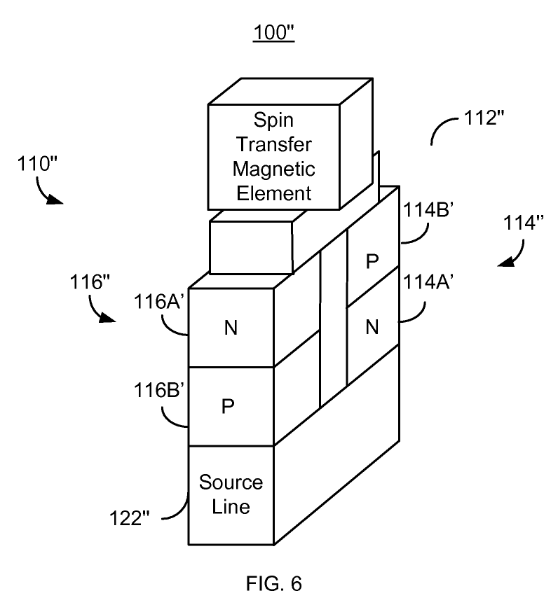

FIG. 6 is a cross-sectional diagram depicting another exemplary embodiment of a portion of a conventional magnetic memory 100″ employing the spin transfer effect. The magnetic memory 100″ is analogous to the magnetic memory 100 and the magnetic memory 100′. Consequently, analogous portions of the magnetic memory 100″ are labeled similarly. Thus, the magnetic memory 100″ includes a magnetic memory cell 110″ including magnetic element 112″ and unidirectional polarity selection devices 114″ and 116″. Also shown is source line 122″. For clarity, the bit line is not shown.

Although only one magnetic memory cell 110″ and source line 122″ are shown, a memory typically includes a plurality of magnetic memory cells 110″ arranged in an array as well as a number of bit lines (not shown) and source lines 122″. In addition, although one magnetic element 112″ is shown, multiple magnetic elements might be used in each cell 110″. The magnetic element 112″ is coupled to the bit line (not shown), while the unidirectional polarity selection devices 114″ and 116″ are coupled to the source line 122″. The magnetic element 112″ may be a spin valve, MTJ, dual spin valve, dual MTJ, or other analogous magnetic element and is configured to be changeable between resistance states by driving a current through the magnetic element 112″. The current changes state of the magnetic element 112″ using the spin transfer torque switching effect.

The unidirectional polarity selection devices 114″ and 116″ are coupled in parallel. In addition, the unidirectional polarity selection devices 114″ and 116″ are configured such that their polarities are opposite. The unidirectional selection devices 114″ and 116″ are vertical diodes. The diode 114″ conducts current in a first direction (from the magnetic element 112″ to the source line 122″) while the diode 116″ conducts current in a second direction opposite to the first direction (from the source line 122″ to the magnetic element 112″). Although two diodes 114″ and 116″ are shown, another number may be used. In operation, the magnetic memory 100″ functions in an analogous manner to the magnetic element 100. In the embodiment shown, the diodes 114″ and 116″ are vertical diodes. Thus, the diode 114″ includes N-region 114A′ and P-region 114B′. Similarly, the diode 116″ includes N-region 116A′ and P-region 116B′.

The magnetic memory 100″ functions in an analogous manner to the magnetic memory 100. Thus, the write current used to set the magnetic element 112″ to a first state is driven in a first direction passes through the magnetic element 112″ and the diode 114″ to the source line 122″. The write current used to set the magnetic element 112″ to a second state is driven in a second direction passes from the source line 122″ and the diode 116″ to the magnetic element 112″. When reading, a read current is driven through the magnetic element 112″. In one embodiment, the read current may be driven in from magnetic element 112″ to the source line 122″ through the diode 114″. In another embodiment, the read current may be driven from the source line 122″, through the diode 116″ and through the magnetic element 112″. In one embodiment, the read current is sufficiently smaller than the write current that the magnetic element 112″ is not inadvertently written. Thus, the magnetic memory 100″ can be written to and read.

In addition, using the magnetic memory cell 110″, smaller cell sizes may be achieved. The N-region 116A′ is on top of the P-region 116B′. Similarly, the P region 114B′ is on the N-region 114A′. Because the regions 114A′ and 114B′ and 116A′ and 116B′ are stacked rather than residing in the same plane, the magnetic storage cell 110″ may occupy less area. Consequently, the magnetic storage cell 110″, as well as the magnetic storage cell 110, may be made smaller. A higher density magnetic memory 100″ may thus be achieved. In order to fabricate the diodes 116″ and 114″, selective-epitaxial-growth (SEG) of single crystalline Si and subsequent doping through implant processes may be used to form the desired P-regions 114B′ and 116B′ and N-regions 114A′ and 116A′. In addition, to achieve small cell size, the local source line 122″ may be provided underneath the diodes 114″ and 116″. In one embodiment, it is estimated that the size of the memory cell 110″ is approximately 10F² with F being the critical lithography dimension. Thus, the magnetic memory 100″ may have a higher density.

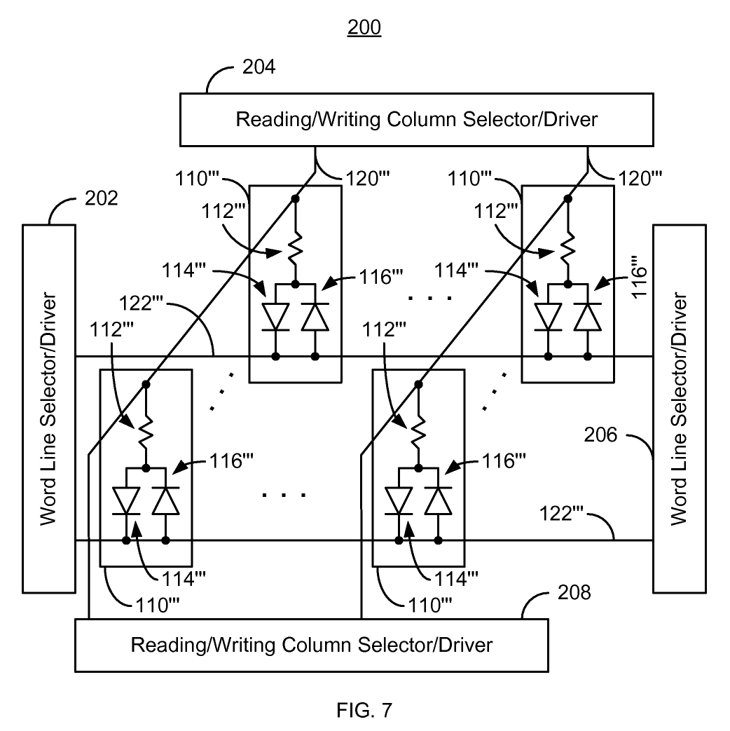

FIG. 7 is a diagram depicting an exemplary embodiment of a portion of a magnetic memory 200 employing the spin transfer effect. Magnetic memory cells 110′″ including magnetic element 112′″ and unidirectional polarity selection devices 114′″ and 116′″ are shown. In addition, bit lines 120′″ and source lines 122′″ are shown. The magnetic memory cells 110′″ are analogous to the magnetic memory cells 110, 110′, and 110″. Thus, the magnetic memory cells 110′″ function in an analogous manner to that described for the magnetic memory 100, 100′, and 100″. In addition, also shown are word line selector/drivers 202 and 206 and reading/writing column selector/drivers 204 and 208. For clarity, other components such as sense amplifiers and control logic are not shown.

During writing operations, the column selector/drivers 204 and 208 select the column of the bit being written, while the word line selector/drivers 202 and 206 select the source line 122′″ of the cell 110′″ being written. For writing to the first state, the reading/writing column selector/drivers 204/208 supplies a high voltage to the appropriate bit line(s) 120′″, while the word line selector/drivers 202/206 supplies a low voltage. For writing to a second state, the reading/writing column selector/drivers 204/208 supplies a low voltage to the appropriate bit line(s) 120′″, while the word line selector/driver 202/206 supplies a high voltage. Thus, the voltage applied by the word line selector/drivers 202 and 206 depends upon the state to which the cell 110′″ is written. Similarly, the voltage applied by the reading/writing column selector/drivers 204 and 208 depends upon the state to which the cell 110′″ is written.

During reading operations, the reading/writing column selector/drivers 204/208 select the columns, or bit lines 120′″ for the bit being read and reference column(s) if any. The word line selector/drivers 202/206 select the source lines 122′″ of the bit being read and also reference bit(s). In one embodiment, for the column selector/drivers 204/208 supply a voltage lower for reading than is used for writing. Also in a read operation, the word line selector/drivers 202/206 supply a lower voltage. In one embodiment, this lower voltage is ground. In one embodiment, the read signal(s) from the bit lines 120′″ are fed into a sense amplifier (not shown) to detect the states of the memory bit. Output signals are sent out to data outputs (not shown).

Thus, the magnetic memory 200 may be read and written. In addition, the magnetic memory 200 may also be integrated to higher densities, particularly if vertical diodes are used for the unidirectional polarity selection devices 144′″ and 116′″. Further, the use of separate word and source lines may be avoided. Instead, a single set of lines 122′″ is used. Consequently, integration to higher densities might further be facilitated.

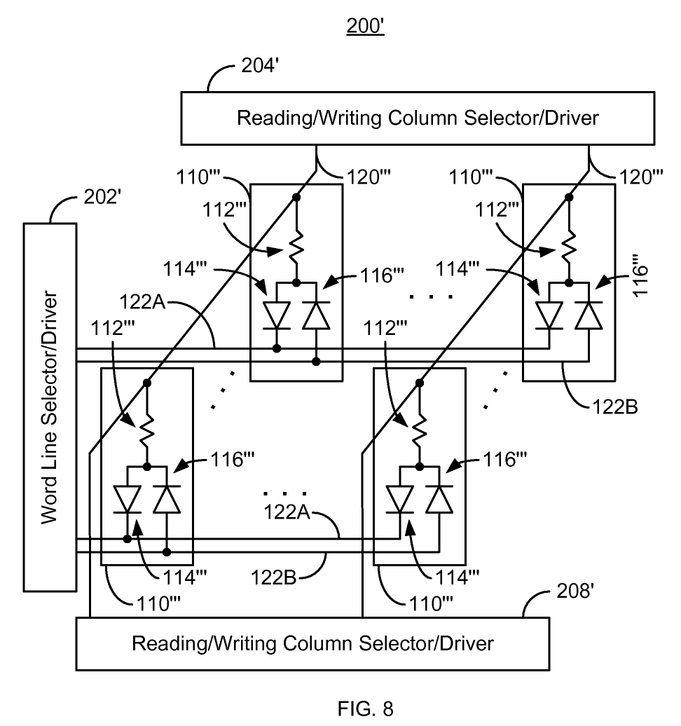

FIG. 8 is a diagram depicting another exemplary embodiment of a portion of a magnetic memory 200′ employing the spin transfer effect. The magnetic memory 200′ is analogous to the magnetic memory 200. Thus, components are labeled similarly. The magnetic memory cells 110′″ include magnetic element 112′″ and unidirectional polarity selection devices 114′″ and 116′″. The magnetic memory cells 110′″ are analogous to the magnetic memory cells 110, 110′, and 110″ and, therefore, function in an analogous manner to that described for the magnetic memory 100, 100′, and 100″.

Also shown are word line selector/drivers 202′ and reading/writing column selector/drivers 204′ and 208′. In addition, bit lines 120′″ and source lines 122A and 122B are shown. The source lines 122A and 122B are used to provide separate source lines for unidirectional polarity selection devices 114′″ and 116′″, respectively, that are oriented in the same direction. In addition, only a single word line selector/driver 202′ may be used. For clarity, other components such as sense amplifiers and control logic are not shown.

During a writing operation, the column selector/drivers 204′ and 208′ select the column of the bit being written. The word line selector/driver 202′ selects the source line 122A or 1222B of the cell 110′″ being written. For writing to the first state, the reading/writing column selector/drivers 204′/208′ supplies a high voltage to the appropriate bit line(s) 120′″, while the word line selector/driver 202′ supplies a low voltage to the appropriate line 122A or 122B. For writing to a second state, the reading/writing column selector/drivers 204′/208′ supplies a low voltage to the appropriate bit line(s) 120′″, while the word line selector/driver 202′ supplies a high voltage to the appropriate bit line 122A or 122B. Thus, the voltage applied by the word line selector/driver 202′ and the line 122A or 122B to which the voltage is applied depends upon the state to which the cell 110′″ is written. Similarly, the voltage applied by the reading/writing column selector/drivers 204′ and 208′ depends upon the state to which the cell 110′″ is written.

During a reading operation, the reading/writing column selector/drivers 204′/208′ select the columns for the bit being read and reference column(s) if any. Thus, the appropriate bit lines 120′″ are activated. The word line selector/driver 202′ selects the source line 122A or 122B of the bit being read and any reference bit(s). In one embodiment, for the column selector/drivers 204′/208′ supply a voltage lower for reading than is used for writing. Also in a read operation, the word line selector/driver 202′ supplies a lower voltage. In one embodiment, this lower voltage is ground. In one embodiment, the read signal(s) from the bit lines 120′″ are fed into a sense amplifier (not shown) to detect the states of the memory bit. Output signals are sent out to data outputs (not shown).

Thus, the magnetic memory 200′ may be read and written. In addition, the magnetic memory 200′ may also be integrated to higher densities, particularly if vertical diodes are used for the unidirectional polarity selection devices 144′″ and 116′″. Further, a single word line selector/driver 202′ may be used. Moreover, use of separate lines 122A and 122B also allows a global bias voltage to be applied to cells along the same bit line 120′″. Consequently, integration to higher densities might further be facilitated.

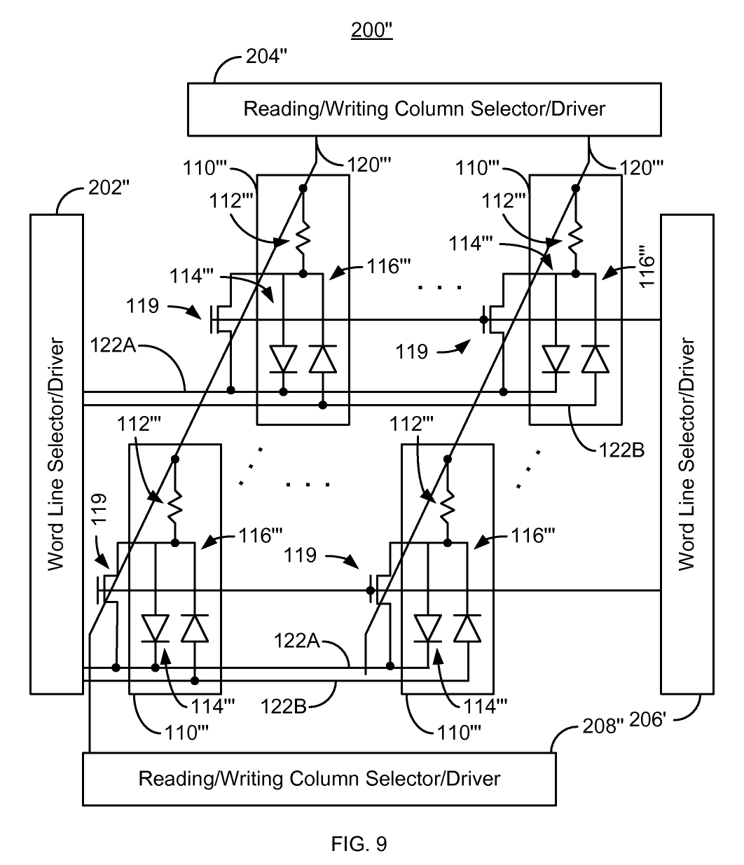

FIG. 9 is a diagram depicting an exemplary embodiment of a portion of a magnetic memory 200″ employing the spin transfer effect. The magnetic memory 200″ is analogous to the magnetic memory 200. Consequently, components are labeled in a similar manner. The magnetic memory cells 110′″ function in an analogous manner to that described for the magnetic memory 100, 100′, and 100″. For clarity, other components such as sense amplifiers and control logic are not shown.

In addition to the source lines 122A and 122B being used for diodes 114′″ and 116′″, respectively, an additional word line selector/driver 206′ is shown. The source lines 122A and 122B are used to provide separate source lines for unidirectional polarity selection devices 114′″ and 116′″, respectively, that are oriented in the same direction. Moreover, clamping devices 119 are also shown. In one embodiment, the clamping devices 119 are transistors.

During writing operations, the magnetic memory 200″ functions in an analogous manner to the memory 200. During read operations, the clamping devices 119 may also be activated using the word line selector/driver 206′. Consequently, read current may flow not only through the unidirectional selection device 114′″ or 116′″, but also through the clamping device 119.

Thus, the magnetic memory 200″ may be read and written. In addition, the magnetic memory 200″ may also be integrated to higher densities, particularly if vertical diodes are used for the unidirectional polarity selection devices 144′″ and 116′″. Use of separate lines 122A and 122B allows a global bias voltage to be applied to cells along the same bit line 120′″. Further, the clamping devices 119 may be used to clamp possible current or voltage spikes from the unidirectional selection devices 114′″ and 116′″. Thus, write disturbs due to the read current may be reduced. Consequently, integration to higher densities might further be facilitated.

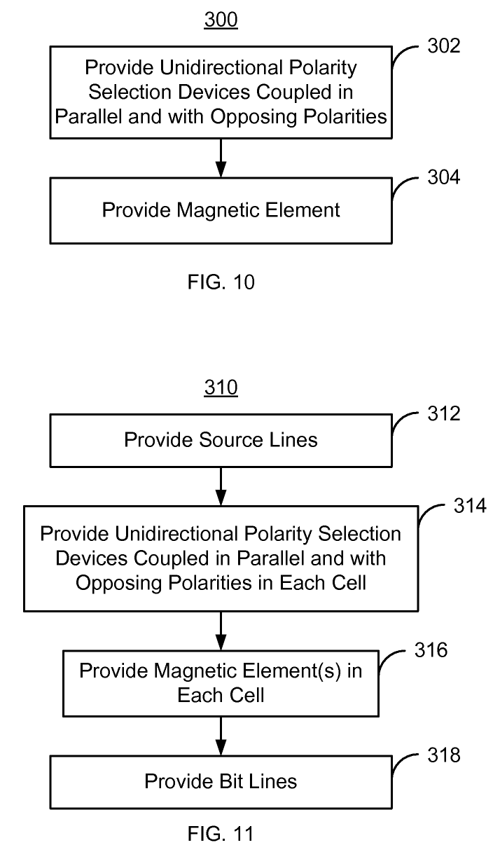

FIG. 10 is a diagram depicting an exemplary embodiment of a method 300 for providing a portion of a magnetic memory employing the spin transfer effect. In particular, the method 300 may be used for providing the magnetic storage cell 110/110′/110″/110′″. Unidirectional polarity selection devices are provided, via step 302. In one embodiment, step 302 includes coupling the selection devices in parallel and with opposing polarities. In one embodiment, step 302 includes providing diodes and coupling the diodes with opposite polarities. Also in one embodiment, the diodes provided in step 302 are vertical diodes. Thus, using the method 300, the magnetic storage cells 110/110′/110″/110′″ may be provided.

The magnetic element 112/112′/112″/112′″ is provided, via step 304. Thus, step 304 includes providing a magnetic element programmable by a current driving through the magnetic element 112/112′/112″/112′″. In one embodiment, step 304 includes providing a MTJ or dual MTJ capable of being programmed using the spin transfer effect.

FIG. 11 is a diagram depicting an exemplary embodiment of a method 310 for providing a magnetic memory employing the spin transfer effect. The method 310 is described in the context of the memory 200. However, the method 310 may be used in providing another memory.

The source lines 122′″ are provided, via step 312. In one embodiment, step 312 includes implanting the source lines 122′″. The unidirectional polarity selection devices 114′″ and 116′″ are provided for each magnetic storage cell, via step 314. In one embodiment, step 314 includes forming vertical diodes, such as the diodes 114′″ and 116′″. However, in another embodiment, the diodes could have other configurations. Step 314 also includes coupling the unidirectional polarity selection devices such that they have opposing polarities. The magnetic element(s) 112′″ are provided in each cell 110′″, via step 316. Thus, magnetic devices capable of being programmed by a current driven through the magnetic element are provided in step 316. In one embodiment step 316 include providing magnetic elements that can be programmed using spin transfer. Step 316 includes coupling the magnetic element(s) 112′″ to the unidirectional polarity selection devices 114′″ and 116′″. The bit lines 120′″ are provided, via step 318. Step 318 includes coupling the bit lines 120′″ to the appropriate magnetic element 112′″. Thus, using the method 310, the magnetic memory 200 may be provided. In one embodiment, the memory 200 provided by the method 310 may be integrated to higher densities.

A method and system for providing a magnetic memory has been disclosed. The present invention has been described in accordance with the embodiments shown, and one of ordinary skill in the art will readily recognize that there could be variations to the embodiments, and any variations would be within the spirit and scope of the present invention. Accordingly, many modifications may be made by one of ordinary skill in the art without departing from the spirit and scope of the appended claims.

We claim:

1. A magnetic memory cell comprising:
at least one magnetic element, the at least one magnetic element being programmable using at least one write current driven through the magnetic element; and
a plurality of unidirectional polarity selection devices coupled with the at least one magnetic element, the plurality of unidirectional polarity selection devices connected in parallel, the plurality of unidirectional polarity selection devices being coupled to have opposing polarity.

2. The magnetic memory cell of claim 1 wherein the plurality of unidirectional polarity selection devices further includes a pair of diodes.

3. The magnetic memory cell of claim 2 wherein the pair of diodes are coupled such that current is driven through only one diode of the pair of diodes at a time.

4. The magnetic memory cell of claim 2 wherein the pair of diodes includes a pair of vertical diodes.

5. A magnetic memory comprising:
a plurality of magnetic storage cells, each of the plurality of magnetic storage cells including at least one magnetic element and a plurality of unidirectional polarity selection devices coupled with the at least one magnetic element, the at least one magnetic element being programmable using at least one write current driven through the magnetic element, the plurality of unidirectional polarity selection devices connected in parallel, the plurality of unidirectional polarity selection devices being coupled to have opposing polarity;
a plurality of bit lines corresponding to the plurality of magnetic storage cells; and
a plurality of source lines corresponding to the plurality of magnetic storage cells.

6. The magnetic memory of claim 5 wherein the plurality of bit lines are coupled with the at least one magnetic element of the plurality of storage cells.

7. The magnetic memory of claim 5 wherein the plurality of unidirectional polarity selection devices further includes a pair of diodes.

8. The magnetic memory of claim 6 wherein the pair of diodes are coupled such that current is driven through only one diode of the pair of diodes at a time.

9. The magnetic memory of claim 6 wherein the pair of diodes includes a pair of vertical diodes.

10. The magnetic memory of claim 6 wherein the plurality of word lines further includes a first word line and a second word line for each of a portion of the plurality of magnetic storage cells, the first word line corresponding to a first unidirectional polarity selection device having a first polarity, the second word line corresponding to a second unidirectional polarity selection device having a second polarity opposite to the first polarity.

11. The magnetic memory of claim 10 further comprising:
a plurality of clamping devices coupled with each of the plurality of magnetic storage cells, each of the plurality of clamping devices being coupled in parallel with the plurality of unidirectional polarity selection devices and being separately activated.

12. A method for providing a magnetic memory cell comprising:
providing a plurality of unidirectional polarity selection devices, the plurality of unidirectional polarity selection devices connected in parallel, the plurality of unidirectional polarity selection devices being coupled to have opposing polarity; and
providing at least one magnetic element coupled with the plurality of unidirectional polarity selection devices, the at least one magnetic element being programmable using at least one write current driven through the magnetic element.

13. The method of claim 12 wherein the plurality of unidirectional polarity selection devices further includes a pair of diodes.

14. The method of claim 13 wherein the pair of diodes are coupled such that current is driven through only one diode of the pair of diodes at a time.

15. The method of claim 12 wherein the pair of diodes includes a pair of vertical diodes.

16. A method for providing a magnetic memory comprising:
providing a plurality of magnetic storage cells, each of the plurality of magnetic storage cells including at least one magnetic element and a plurality of unidirectional polarity selection devices coupled with the at least one magnetic element, the at least one magnetic element being programmable using at least one write current driven through the magnetic element, the plurality of unidirectional polarity selection devices connected in parallel, the plurality of unidirectional polarity selection being coupled to have opposing polarity;
providing a plurality of bit lines corresponding to the plurality of magnetic storage cells; and
a plurality of source lines corresponding to the plurality of magnetic storage cells.

17. The method of claim 16 wherein the plurality of unidirectional polarity selection devices further includes a pair of diodes.

18. The method of claim 16 wherein the pair of diodes are coupled such that current is driven through only one diode of the pair of diodes at a time.

19. The method of claim 18 wherein the pair of diodes includes a pair of vertical diodes.

20. The method of claim 16 wherein the plurality of word lines further includes a first word line and a second word line for each of a portion of the plurality of magnetic storage cells, the first word line corresponding to a first unidirectional polarity selection device having a first polarity, the second word line corresponding to a second unidirectional polarity selection device having a second polarity opposite to the first polarity.

21. The method of claim 20 further comprising:
providing a plurality of clamping devices coupled with each of the plurality of magnetic storage cells, each of the plurality of clamping devices being coupled in parallel with the plurality of unidirectional polarity selection devices and being separately activated.
